(19) United States
(12) Patent Application Publication
(10) Pub. No.: US 2026/0343775 A1
(43) Pub. Date: Oct. 29, 2026

(54) POWER SUPPLY DEVICE

(71) Applicant: FSP TECHNOLOGY INC., Taoyuan City (TW)

(72) Inventor: Mao-Kuan LIN, Taoyuan City (TW)

(21) Appl. No.: 19/656,320

(22) Filed: Apr. 23, 2026

Related U.S. Application Data
(60) Provisional application No. 63/795,638, filed on Apr. 28, 2025.

(51) Int. Cl. H05K 7/14; C09D 1/00; C09D 5/18; H02M 3/00

(52) U.S. Cl. CPC H05K 7/1432; C09D 1/00; C09D 5/18; H02M 3/003

(57) ABSTRACT

A power supply device includes a plastic enclosure, a conversion module, and a flame-retardant material. The plastic enclosure includes an inner surface, and an accommodation space formed within the plastic enclosure. The conversion module is disposed within the accommodation space, and the conversion module converts an input source to an output source. The flame-retardant material is disposed between the inner surface and the conversion module so as to form at least one flame-retardant area. The flame-retardant material includes a mixture of titanium dioxide and silicon dioxide to provide a flame-retardant effect.

### CROSS-REFERENCE TO RELATED APPLICATION

This patent application claims the benefit of United States Provisional Patent Application No. 63/795,638, filed Apr. 28, 2025, which is incorporated by reference herein.

### BACKGROUND

### Technical Field

The present disclosure relates to a power supply device, and more particularly to a miniaturized power supply device with flame-retardant function.

### Description of Related Art

The statements in this section merely provide background information related to the present disclosure and do not necessarily constitute prior art.

To meet the demand for portability, existing power supplies or adapters (hereinafter referred to as power supply devices) face increasingly stringent requirements regarding their size, particularly for adapters used with electronic devices (such as mobile phones, laptops, and game consoles), where size is a key consideration for consumers. Although the size of power supply devices has decreased, their output power must still meet the requirements of power supply devices of the original size, thereby forcing an increase in internal power density. As a result, the space available for arranging electronic components is significantly reduced. Typically, the interior of a power supply device contains one or more potential ignition source (PIS) elements, for example, but not limited to, surge arresters (varistors) and power switches. Taking varistors as an example, to prevent the power supply device from malfunctioning or failing due to surge currents or voltage spikes, protective components such as fuses and varistors are inevitably installed at the input terminal of the power supply device to prevent damage to internal components or downstream loads.

In addition to fuses, when an abnormal condition such as an excessive surge or spike occurs at the input source and exceeds the voltage or current ratings of a varistor, the varistors may be burned out. Before the varistor burns out, it typically generates a large amount of heat and flames, which could potentially cause the entire power supply device to catch fire. For example, as shown in the experimental photographs of the miniaturized power supply device 100 of the prior art in FIGS. 1-2, once the varistor burns out due to an abnormal condition, the fire spreads to external components such as the plastic enclosure and circuit board, causing extensive burn-through of the plastic enclosure of the miniaturized power supply device 100. Consequently, there is a risk that flames could penetrate the power supply device 100 and spread to surrounding equipment, thereby resulting in a potential fire hazard.

To avoid the aforementioned issues, it is one of the major objectives of the inventors of the present disclosure to design a power supply device that complies with flammability testing standards, while also being low-cost, lightweight, and without additionally increasing the overall product size.

### SUMMARY

In order to solve the above-mentioned problems, the present disclosure provides a power supply device, the power supply device includes a plastic enclosure, a conversion module, and a flame-retardant material. The plastic enclosure includes an inner surface, and an accommodation space is formed within the plastic enclosure. The conversion module is disposed within the accommodation space, and configured to convert an input source to an output source. The flame-retardant material includes a mixture of titanium dioxide and silicon dioxide. wherein the flame-retardant material is configured to be disposed between the inner surface and the conversion module to form at least one flame-retardant area.

In one embodiment, a thickness of the plastic enclosure is less than or equal to 1.5 mm.

In one embodiment, the conversion module includes at least one potential ignition source element, and the potential ignition source element is disposed within the conversion module in a position adjacent to the flame-retardant area.

In one embodiment, the flame-retardant material further includes a film-forming substance and a volatile solvent, so as to mix with the mixture to form a liquid mixture.

In one embodiment, a ratio of the film-forming substance, titanium dioxide, silicon dioxide, and water is 5:1:1:3.

In one embodiment, the liquid mixture is coated with at least one layer in a first direction to form at least one primer layer, and then at least one layer is coated in a second direction over the primer layer.

In one embodiment, the liquid mixture is an oil-based coating or a water-based coating.

In one embodiment, a thickness of the liquid mixture after curing does not exceed 0.1 mm.

In one embodiment, the power supply device further includes a substrate, one side of the substrate is configured to be coated with the liquid mixture, so as to form a flame-retardant composite component.

In one embodiment, a coating amount of the liquid mixture is 200 to 250 g/m², and the thickness is between 0.16 and 0.2 mm.

In one embodiment, the substrate is an insulating sheet or an insulating tape.

In one embodiment, the substrate is a carbon-containing sheet.

In one embodiment, the liquid mixture further includes a resin-based flame-retardant for enhancing a viscosity of the liquid mixture.

The main purpose and effect of the present disclosure is that the present disclosure primarily uses the mixture of titanium dioxide and silicon dioxide as the flame-retardant material, and accordingly configures it within the power supply device, so that it may ensure meet the specifications of the finished product test in Appendix S.2 of the China GB 4943.1-2022 standard. Furthermore, the flame-retardant material includes effects of low cost, light weight, and no increase in product volume, so that the power supply device not only improves its fire resistance but also gains industrial competitiveness.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a photograph showing the experimental results of a first experimental example of a miniaturized power supply device without flame-retardant functions according to the prior art.

FIG. 2 is a photograph showing the experimental results of a second experimental example of the miniaturized power supply device without flame-retardant functions according to the prior art.

FIG. 3 is a cross-sectional view of a circuit configuration of the miniaturized power supply device having flame-retardant functions according to the present disclosure.

FIG. 4A is a schematic diagram showing an arrangement of a first embodiment of a flame-retardant material according to the present disclosure.

FIG. 4B is a schematic diagram showing an arrangement of a second embodiment of the flame-retardant material according to the present disclosure.

FIG. 4C is a schematic diagram showing an arrangement of a third embodiment of the flame-retardant material according to the present disclosure.

FIG. 4D is a schematic diagram showing an arrangement of a fourth embodiment of the flame-retardant material according to the present disclosure.

FIG. 5A is a product schematic diagram of a first embodiment of a flame-retardant composite component made from the flame-retardant material according to the present disclosure.

FIG. 5B is a product schematic diagram of a second embodiment of the flame-retardant composite component made from the flame-retardant material according to the present disclosure.

FIG. 6A is a structural view of a first embodiment of the miniaturized power supply device having flame-retardant functions according to the present disclosure.

FIG. 6B is a structural view of a second embodiment of the miniaturized power supply device having flame-retardant functions according to the present disclosure.

### DETAILED DESCRIPTION

Reference will now be made to the drawing figures to describe the present disclosure in detail. It will be understood that the drawing figures and exemplified embodiments of present disclosure are not limited to the details thereof.

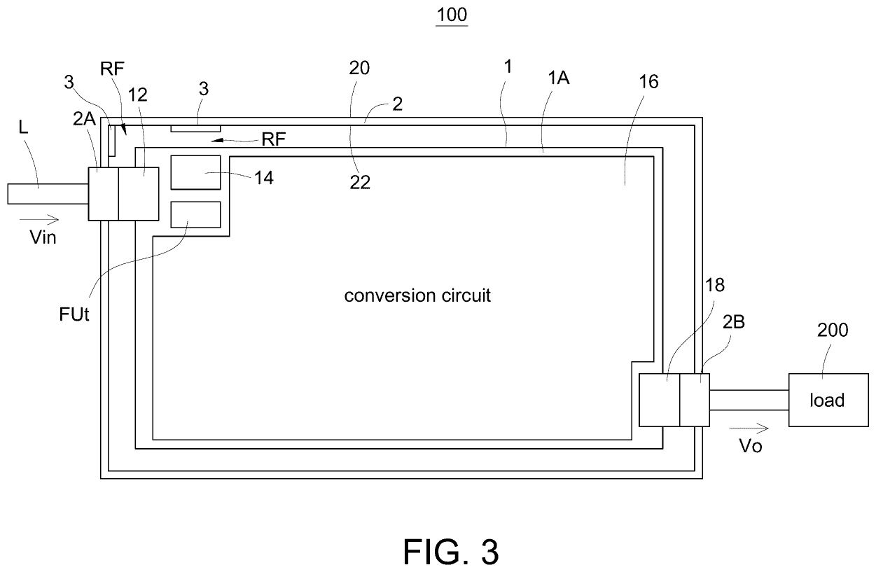

Please refer to FIG. 3, which shows a cross-sectional view of a circuit configuration of a miniaturized power supply device having flame-retardant functions according to the present disclosure. The power supply device 100 is coupled to a power line L and a load 200, and includes a conversion module 1 and a plastic enclosure 2. The conversion module 1 may be configured on circuit board 1A and includes an input terminal 12, a potential ignition source (PIS) element 14, a conversion circuit 16, and an output terminal 18. The input terminal 12 is used to couple to the power line L to receive an input source Vin supplied by the power line L. The PIS element 14 may be, for example but not limited to, a varistor, a power switch, or other components prone to generating heat. Taking the varistor as an example of the PIS element 14, the PIS element 14 is coupled to the input terminal 12 to suppress surges of the input source Vin. The conversion circuit 16 is coupled to the PIS element 14 and converts the input source Vin to an output source Vo. In particular, the conversion circuit 16 may be an isolation conversion circuit (for example, but not limited to, Flyback or Forward) or a non-isolation conversion circuit (for example, but not limited to, Buck or Boost), and it internally includes at least one power switch to convert the input source Vin into the output source Vo by switching the power switch to turn on/off. The output terminal 18 is coupled to the conversion circuit 16 and receives the output source Vo, so as to provide the output source Vo to the load 200.

The plastic enclosure 2 includes an outer surface 20 and an inner surface 22, and an accommodation space is formed therein. Furthermore, the plastic enclosure 2 defines two ports 2A and 2B, and the input terminal 12 and the output terminal 18 are respectively configured at the two ports 2A and 2B (for example, but not limited to, the input terminal 12 being configured at port 2A and the output terminal 18 being configured at port 2B). The conversion module 1 may selectively include a thermal fuse FUt, and the thermal fuse FUt is connected in series with the PIS element 14. The thermal fuse FUt primarily detects overheating generated by the conversion module 1 during abnormal operation and melts accordingly, thereby disconnecting a path between the input terminal 12 and the PIS element 14 of the conversion module 1 to prevent the occurrence of a fire. In one embodiment of the present disclosure, the configuration of the thermal fuse FUt shown in FIG. 3 is merely illustrative. In practice, it is not limited to the position shown in FIG. 3, and it may generally be configured near the input terminal 12.

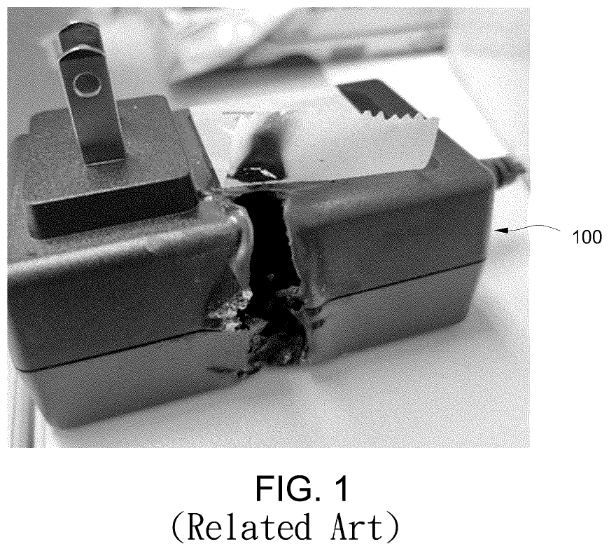

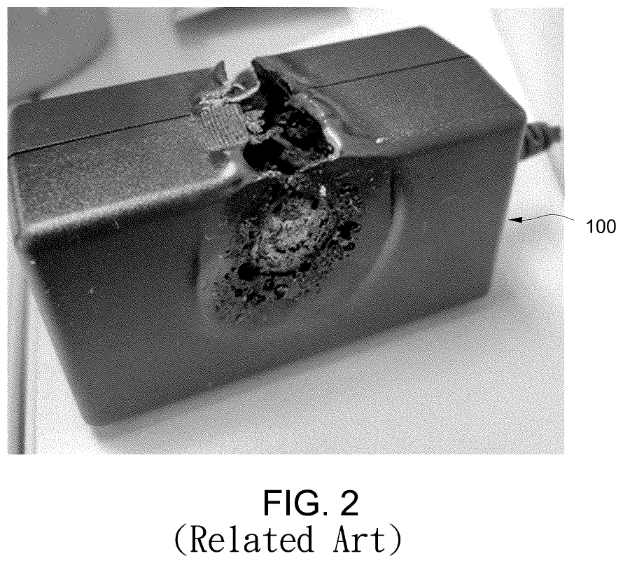

Generally speaking, to prevent a PIS element 14 (such as the varistor referred to in this embodiment) from burning out due to an abnormal condition and causing the plastic enclosure 2 of the miniaturized power supply device 100 to suffer extensive burn-through from the inside, as shown in FIGS. 1 and 2, the power supply device 100 must comply with applicable safety standards. Therefore, before leaving the factory, the power supply device 100 must pass safety compliance testing and comply with relevant safety regulations. Generally, the thickness of the plastic enclosure 2 of the power supply device 100 is approximately less than or equal to 1.5 mm. Furthermore, according to the flammability test specified in Appendix S.2 of the China GB 4943.1-2022 standard, this flammability test must be conducted using an open flame. Specifically, the procedure for this flammability test involves contacting one side of the plastic enclosure 2 with the tip of the open flame for at least 60 seconds, and the other side of the plastic enclosure 2 is provided with flammable fabric. During the test (that is, while the open flame is in contact with the plastic enclosure 2), the flammable fabric must not ignite. However, under such conditions of prolonged direct contact with the flame, existing plastic enclosures 2 are typically burned through, causing the flammable fabric to ignite, thereby failing to satisfy the requirements of the flammability test specified in Appendix S.2.

Therefore, the methods currently known in the industry for improving the fire resistance of plastic enclosures of power supply devices to meet the specifications of the flammability test in Appendix S.2 are as follows:
(1) Using plastic enclosures reinforced with glass fiber: however, plastic enclosures containing glass fiber tend to be relatively brittle and are difficult to pass safety tests, such as a free fall test.
(2) Potting resin inside the product: this affects heat dissipation and increases product weight, which does not conform to the trend of lightweight design.
(3) Increasing the enclosure thickness to approximately 3 mm: this increases the product volume and weight, which contradicts the current trend of miniaturization and thinness.
(4) Using metal sheets inside the enclosure: this will not only increase the weight of the product, but also may adversely affect the insulation distance, further affecting the product volume.
(5) Using inorganic materials (such as graphite paper) inside the enclosure: however, the use of such materials significantly increases product cost, which is unfavorable to product cost-effectiveness.

Therefore, the present disclosure primarily involves configuring a special flame-retardant material 3 within the power supply device 100 to enable compliance with the specifications of the flammability test in Appendix S.2 of the China GB 4943.1-2022 standard. Furthermore, the flame-retardant material 3 features low cost, light weight, and does not additionally increase the overall product volume, so that the power supply device 100 not only improves its fire resistance but also enhances its industrial competitiveness. Specifically, with further reference to FIG. 3, the power supply device 100 of the present disclosure forms at least one flame-retardant area RF between the inner surface 22 of the plastic enclosure 2 and the conversion module 1. Preferably, the location of the flame-retardant area RF corresponds to the area between the PIS element 14 and the plastic enclosure 2. That is, the flame-retardant area RF substantially refers to the region between the location of the PIS element 14 and the inner surface 22 of the plastic enclosure 2. The power supply device 100 of the present disclosure is configured with flame-retardant material 3 to form the flame-retardant area RF and enhance the fire resistance of the plastic enclosure 2. Accordingly, even when one side of the plastic enclosure 2 is contacted by the tip of an open flame for at least 60 seconds, the flame-retardant material 3 disposed on that side can prevent the plastic enclosure 2 from being directly burned through. Consequently, the flammable fabric disposed on the other side of the plastic enclosure 2 will not ignite, thereby enabling the power supply device 100 of the present disclosure to meet the specifications of the flammability test in Appendix S.2.

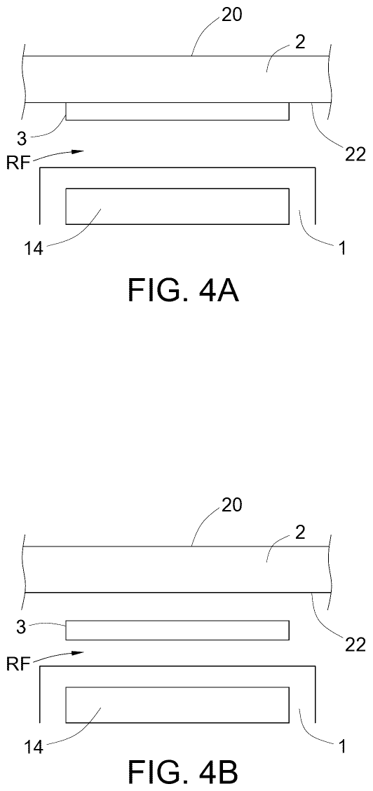

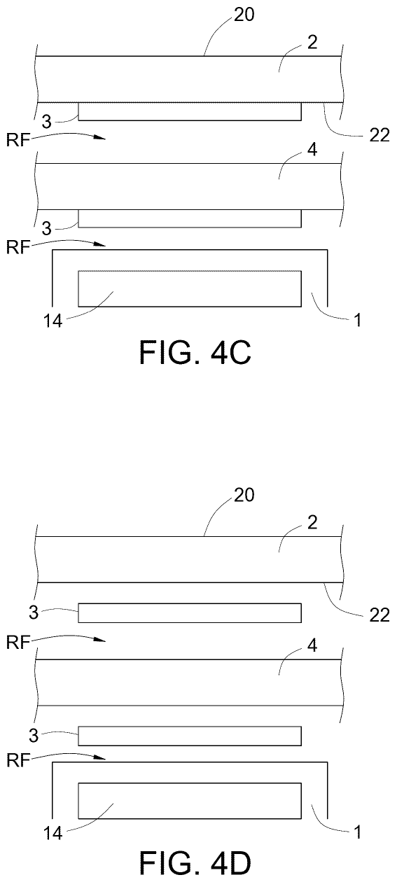

Refer to FIGS. 4A-4D, which show schematic diagrams showing an arrangement of first to fourth embodiments of the flame-retardant material according to the present disclosure. Furthermore, the power supply device 100 of the present disclosure may configure the flame-retardant material 3 in the flame-retardant area RF in various ways (as shown in FIGS. 4A-4D) to improve the fire resistance of the plastic enclosure 2. The flame-retardant material 3 includes mixture of titanium dioxide and silicon dioxide. In one embodiment, the flame-retardant material 3 may be manufactured as products such as flame-retardant coatings or flame-retardant composite components (for example, but not limited to, flame-retardant tape or flame-retardant sheets), and may be appropriately disposed between the inner surface 22 and the conversion module 1 according to the properties of the product, so as to form the flame-retardant area RF. For example, but not limited to, when there is no barrier between the inner surface 22 and the conversion module 1, the flame-retardant material 3 in the form of flame-retardant tape or flame-retardant coating may be directly adhered to the inner surface 22 of the plastic enclosure 2 (as shown in FIG. 4A), or the flame-retardant material 3 in the form of a flame-retardant sheet may be disposed between the inner surface 22 and the conversion module 1 to serve as barrier (as shown in FIG. 4B). Thus, a flame-retardant area RF may be formed. Conversely, when a barrier material 4 is present between the inner surface 22 and the conversion module 1 (for example, but not limited to, a heat sink), the flame-retardant material 3 in the form of flame-retardant tape or flame-retardant coating may be disposed to the inner surface 22 and/or the barrier material 4 (as shown in FIG. 4C), or the flame-retardant material 3 in the form of a flame-retardant sheet may be disposed between the two gaps among these three components (as shown in FIG. 4D). In this way, two flame-retardant regions RF that substantially overlap may be formed, thereby providing a dual-barrier structure and improving the flame-retardant effect.

Referring to FIGS. 3-4D, in an embodiment where the flame-retardant material 3 is formulated as the flame-retardant coating, the flame-retardant material 3 further includes a film-forming substance and a volatile solvent. The film-forming substance, volatile solvent, and the mixture of titanium dioxide and silicon dioxide are mixed to form a liquid mixture, so that it becomes a coating-type product capable of being applied to the inner surface 22 of the plastic enclosure 2. Specifically, the ratio of the film-forming substance, titanium dioxide, silicon dioxide and water is 6~4:0.5~2:0.5~2:2~4 (the total sum being 10). Preferably, the ratio of film-forming substance, titanium dioxide, silicon dioxide and water may be 5:1:1:3 to provide a better expansion rate and increase the fire-retardant effect. Furthermore, resin-based flame-retardants may be selectively added to the liquid mixture to fine-tune the proportions (further details will be described later). Furthermore, the flame-retardant coating may be a solvent-based coating (for example, but not limited to, oil-based paint), a water-based coating (for example, but not limited to, water-based paint), putty, clay, or similar coating materials. Moreover, solvent-based or water-based coatings are preferred embodiments. When the flame-retardant coating is a solvent-based coating, the film-forming substance may be a resin capable of cross-linking and curing through reaction with oxygen in the air, such as alkyd resin, polyurethane (PU) or epoxy resin. Furthermore, the volatile solvents may include organic solvents used to dissolve the resin and adjust viscosity, such as mineral spirits, xylene, naphtha, and the like.

Conversely, when the flame-retardant coating is water-based, the film-forming substance may be an emulsion or dispersion using water as the dispersion medium, such as acrylic resin, polyurethane dispersion (PU dispersion) or water-based epoxy emulsion. Furthermore, the volatile solvent may consist primarily of water, supplemented by a small amount of coalescing agent (for example, but not limited to, alcohol ethers such as butyl carbitol), so as to assist the resin particles in melting and bonding together after the water has evaporated. On the other hand, in an embodiment where the flame-retardant material 3 is provided as the flame-retardant coating product, the density of the flame-retardant material 3 is preferably about 1.25 kg/L, the pH value is preferably in a range of 7 to 9, the viscosity (at room temperature, generally 25 °C) is preferably in a range of 500-1000 csp, and the decomposition temperature is generally about 250 °C. When the flame-retardant coating is heated, it expands to form a dense (its expansion ratio exceeds 50 times), weakly conductive foam layer, enabling it to withstand temperatures exceeding 1000 °C and effectively protect the substrate. In one embodiment, the liquid mixture may further selectively include a resin-based flame-retardant to improve the viscosity of the liquid mixture, so that during application, the liquid mixture adheres more readily to the surface of the object. In this way, the viscosity of the liquid mixture may be adaptively adjusted according to the material of the object being coated, so as to provide improved adhesion. Therefore, the flame-retardant material 3 of the present disclosure functions as an intumescent flame-retardant agent, causing it to expand upon exposure to heat to form a charred layer, so as to achieve flame retardancy effect. Furthermore, the addition of resin-based flame-retardants agent makes it easier to adhere to plastic surfaces, thereby providing good adhesion performance.

When the flame-retardant material 3 is a flame-retardant coating, it may be applied to the inner surface 22 of the plastic enclosure 2 or to the areas most in need of protection by means of brushing, spraying, rolling or trowelling. As the method and density of coating the flame-retardant coating significantly affects its flame-retardant performance, the flame-retardant performance is poorer when the coating density is relatively low, and conversely, better when the coating density is higher. Therefore, if flame-retardant material 3 is applied by brushing, rolling or trowelling, at least two coating layers are required. That is, after the flame-retardant material 3 is coated in at least one layer in a first direction onto the inner surface 22 of the plastic enclosure 2 to form a primer layer, at least one layer is coated in a second direction over the primer layer. The first and second directions are staggered and preferably perpendicular, so as to ensure that no gaps are formed. In this way, the thickness of the flame-retardant coating after curing does not exceed 0.1 mm, thereby achieving the effect that the configuration of the flame-retardant material does not additionally increase the product volume.

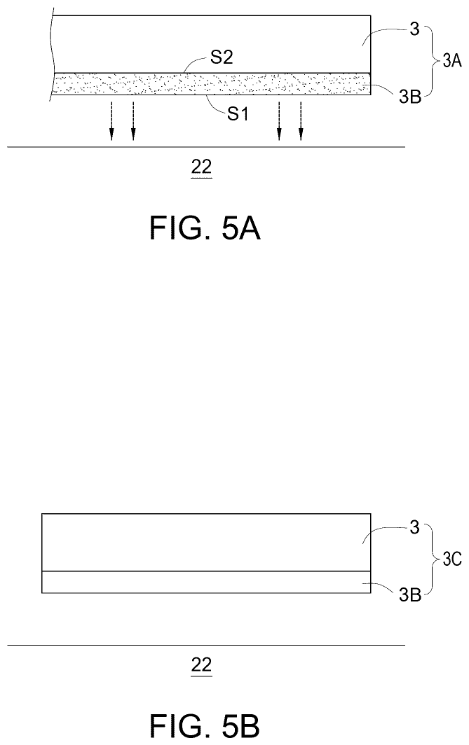

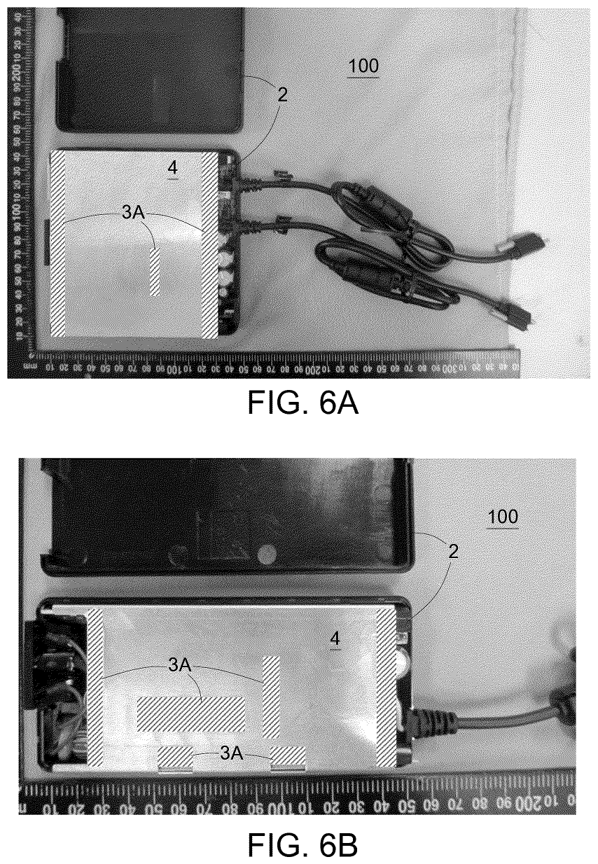

Referring to FIG. 5A, which shows a product schematic diagram of a first embodiment of a flame-retardant composite component made from the flame-retardant material according to the present disclosure, and also refer to FIGS. 3-4D. In FIG. 5A, a flame-retardant tape 3A made from the flame-retardant material 3 is provided as an illustrative example. Specifically, the flame-retardant tape 3A includes the flame-retardant material 3 and a substrate 3B, and the substrate 3B may be an insulating tape. The insulating tape includes a first surface S1 and a second surface S2, and the first surface S1 may be adhered to the inner surface 22 of the plastic enclosure 2. The second surface S2 of the insulating tape is used for coating with the liquid mixture, so that the insulating tape and the liquid mixture form the flame-retardant tape 3A (i.e., a flame-retardant composite component). Specifically, a coating amount of the liquid mixture is about 200-250 g/m², and a thickness ranging from 0.16 to 0.2 mm is a preferred embodiment. This ensures that bending the insulating tape will not easily cause the cured liquid mixture to crack. Therefore, the flame-retardant tape 3A may be cut and adhered to, for example but not limited to, the plastic enclosure 2, insulating sheets, or heat sinks, so that the areas where it is adhered provide flame-retardant functions. Specifically, with reference to FIGS. 6A and 6B, which show structural view of the miniaturized power supply device having flame-retardant functions according to the present disclosure. In FIGS. 6A and 6B, the interior of the plastic enclosure 2 of the power supply device 100 includes a barrier material 4 (for example, but not limited to, a metal shield). The metal shield provides the power supply device 100 with improved heat dissipation capabilities and may further serve as an electromagnetic interference (EMI) shield to reduce electromagnetic interference. Furthermore, the flame-retardant tape 3A may be adhered to the barrier material 4, so as to provide a flame-retardant function at the adhered location.

Referring to FIG. 5B, which shows a product schematic diagram of a second embodiment of the flame-retardant composite component made from the flame-retardant material according to the present disclosure, and also refer to FIGS. 3-5A. In FIG. 5B, a flame-retardant sheet 3C made from the flame-retardant material 3 is provided as an illustrative example. The flame-retardant sheet 3C includes the flame-retardant material 3 and a substrate 3B, and the substrate 3B may be an insulating sheet. The insulating sheet may likewise include a first surface S1 and a second surface S2, and at least one of the first surface S1 and the second surface S2 is used for coating with the liquid mixture, so that the insulating sheet and the liquid mixture form the flame-retardant sheet 3C (i.e., a flame-retardant composite component). That is, the insulating sheet may have the liquid mixture coated on only one side, or on both sides. When the insulating sheet has the liquid mixture coated on only one side, the other side of the insulating sheet may be selectively provided with adhesive properties, so as to adhere to the inner surface 22 of the plastic enclosure 2, or may be non-adhesive so as to be configured in a gap as shown in FIG. 4D. Conversely, when both sides of the insulating sheet are coated with the liquid mixture, the insulating sheet is preferably configured within the gap shown in FIG. 4D.

As shown in FIGS. 5A and 5B, the aforementioned substrate may be selected from, for example but not limited to, IS250A insulating sheets (0.24 mm), PIA220 tape (0.05 mm) or AL50M aluminium foil Mylar (0.05 mm) as preferred embodiments. Furthermore, with reference to FIG. 5B, the substrate 3B may also be a carbon-containing sheet, and the carbon-containing sheet may include, but are not limited to, paper products (e.g., tissue paper, toilet paper, kitchen roll). In addition, the liquid mixture may be selective coated on one or both sides of the carbon-containing sheet. Such products may be damaged due to external forces exerted during brush coating of the liquid mixture, the liquid mixture is preferably applied by spraying onto such products. In summary, the features of the flame-retardant material 3 presented in FIGS. 4 to 5B may be integratively applied to the power supply device 100 shown in FIG. 3, enabling it to possess all the aforementioned characteristics. For example, but not limited to, the flame-retardant tape 3A shown in FIG. 5A may be adhered to the position shown in FIG. 4A, and the flame-retardant material 3 may be coated on the substrate 3B using staggered brush coating (with at least two coating layers applied). By analogy, and is not repeated description thereto.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims. Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A power supply device, comprising:
a plastic enclosure comprising an inner surface, and an accommodation space formed within the plastic enclosure,
a conversion module disposed within the accommodation space, and configured to convert an input source to an output source, and
a flame-retardant material comprising a mixture of titanium dioxide and silicon dioxide,
wherein the flame-retardant material is configured to be disposed between the inner surface and the conversion module to form at least one flame-retardant area.

2. The power supply device as claimed in claim 1, wherein a thickness of the plastic enclosure is less than or equal to 1.5 mm.

3. The power supply device as claimed in claim 1, wherein the conversion module comprises:
at least one potential ignition source element disposed within the conversion module in a position adjacent to the flame-retardant area.

4. The power supply device as claimed in claim 1, wherein the flame-retardant material further comprises a film-forming substance and a volatile solvent, so as to mix with the mixture to form a liquid mixture.

5. The power supply device as claimed in claim 4, wherein a ratio of the film-forming substance, titanium dioxide, silicon dioxide, and water is 5:1:1:3.

6. The power supply device as claimed in claim 5, wherein the liquid mixture is coated with at least one layer in a first direction to form at least one primer layer, and then at least one layer is coated in a second direction over the primer layer.

7. The power supply device as claimed in claim 6, wherein the liquid mixture is an oil-based coating or a water-based coating.

8. The power supply device as claimed in claim 6, wherein a thickness of the liquid mixture after curing does not exceed 0.1 mm.

9. The power supply device as claimed in claim 5, further comprising:
a substrate, one surface of the substrate configured to be coated with the liquid mixture, so as to form a flame-retardant composite component.

10. The power supply device as claimed in claim 9, wherein a coating amount of the liquid mixture is 200 to 250 g/m², and the thickness is between 0.16 and 0.2 mm.

11. The power supply device as claimed in claim 9, wherein the substrate is an insulating sheet or an insulating tape.

12. The power supply device as claimed in claim 9, wherein the substrate is a carbon-containing sheet.

13. The power supply device as claimed in claim 4, wherein the liquid mixture further comprises a resin-based flame-retardant for enhancing a viscosity of the liquid mixture.
